(19) United States
(12) Patent Application Publication
(10) Pub. No.: US 2013/0299771 A1
(43) Pub. Date: Nov. 14, 2013

(54) Semiconductor Device Including Transistor

(71) Applicant: SAMSUNG ELECTRONICS CO., LTD., Suwon-si (KR)

(72) Inventors: Sun-pil Youn, Seoul (KR); Dong-won Kim, Seongnam-si (KR); Taek-sung Kim, Yongin-si (KR)

(21) Appl. No.: 13/748,622

(22) Filed: Jan. 24, 2013

(30) Foreign Application Priority Data
May 10, 2012 (KR) 10-2012-0049777

(51) Int. Cl. H01L 29/78; H01L 27/092

(52) U.S. Cl. CPC H01L 29/78; H01L 27/092
USPC 257/9; 257/402; 257/369

(57) ABSTRACT

A semiconductor device has a semiconductor body including a source region, a channel region, and a drain region, which are sequentially arranged in a longitudinal direction and are doped with the same type of impurity, a gate electrode including metal, and a gate dielectric layer interposed between the semiconductor body and the gate electrode.

### CROSS-REFERENCE TO RELATED APPLICATION

This application claims the benefit under 35 U.S.C. §119 of Korean Patent Application No. 10-2012-0049777, filed on May 10, 2012, in the Korean Intellectual Property Office, the disclosure of which is incorporated herein in its entirety by reference.

### BACKGROUND

The inventive concept relates to a semiconductor device, and more particularly, to a semiconductor device including a transistor.

In order provide high speed, high performance, and low power consumption semiconductor devices, there is a need to reduce the size of transistors that are used in such devices while maintaining the driving performance of these transistors. Research has been conducted into transistors that have channels having three-dimensional structures as one possible means for increasing the device density in an integrated circuit.

### SUMMARY

The inventive concept provides a semiconductor device having improved on/off properties while still having stable and improved performance in a micro field effect transistor.

According to an aspect of the inventive concept, there is provided a semiconductor device including a semiconductor body including a source region, a channel region, and a drain region, which are sequentially arranged in a longitudinal direction and are doped with the same type of impurity; a gate electrode formed on the channel region and including metal; and a gate dielectric layer disposed between the semiconductor body and the gate electrode.

According to another aspect of the inventive concept, there is provided a semiconductor device including a first MOS transistor and a second MOS transistor. The first MOS transistor includes a first semiconductor body including a first source region, a first channel region, and a first drain region, which are sequentially arranged in a longitudinal direction of the first semiconductor body and are doped with a first conductive type impurity; a first gate electrode formed on the first channel region and including a first metal; and a gate dielectric layer interposed between the first semiconductor body and the first gate electrode. The second MOS transistor includes a second semiconductor body including a second source region, a second channel region, and a second drain region, which are sequentially arranged in a longitudinal direction of the second semiconductor body and are doped with a second conductive type impurity that is opposite to the first conductive type impurity; a second gate electrode formed on the second channel region and including a second metal that is different from the first metal; and a second gate dielectric layer interposed between the second semiconductor body and the second gate electrode.

### BRIEF DESCRIPTION OF THE DRAWINGS

Exemplary embodiments of the inventive concept will be more clearly understood from the following detailed description taken in conjunction with the accompanying drawings in which:

FIG. 1 is a partial perspective view of a semiconductor device according to an embodiment of the inventive concept;

FIG. 2 is a cross-sectional view of the semiconductor device taken along line II-II′ of FIG. 1 according to an embodiment of the inventive concept;

FIGS. 3A through 3D are cross-sectional views of some components of semiconductor devices according to embodiments of the inventive concept;

FIG. 3E is a perspective view of a semiconductor device according to another embodiment of the inventive concept;

FIGS. 4A through 4C are graphs showing impurity doping gradients in channel regions of the semiconductor devices shown in FIGS. 3C and 3D according to embodiments of the inventive concept;

FIGS. 5A through 5D are cross-sectional views showing sequential processes of a method of manufacturing a semiconductor device according to an embodiment of the inventive concept;

FIGS. 6A through 6E are cross-sectional views showing sequential processes of a method of manufacturing a semiconductor device according to another embodiment of the inventive concept;

FIGS. 7A through 7C are cross-sectional views showing sequential processes of a method of manufacturing a semiconductor device according to another embodiment of the inventive concept;

FIGS. 8A through 8C are diagrams of a semiconductor device according to an embodiment of the inventive concept, where FIG. 8A is a plan view of the semiconductor device, FIG. 8B is a cross-sectional view of the semiconductor device taken along line 8B1-8B1′ and line 8B2-8B2′ of FIG. 8A, and FIG. 8C is a cross-sectional view of the semiconductor device taken along line 8C1-8C1′ and line 8C2-8C2′ of FIG. 8A;

FIG. 9 is a cross-sectional view of a semiconductor device according to another embodiment of the inventive concept

FIG. 10 is a perspective view of a semiconductor device according to another embodiment of the inventive concept;

FIG. 11A is a cross-sectional view of the semiconductor device taken along line XIA-XIA′ of FIG. 10;

FIG. 11B is a cross-sectional view of the semiconductor device taken along line XIB-XIB′ of FIG. 10;

FIGS. 12A through 12D are cross-sectional views of semiconductor devices according to embodiments of the inventive concept;

FIGS. 13A through 13C are perspective views showing sequential processes of a method of manufacturing a semiconductor device according to an embodiment of the inventive concept;

FIG. 14 is a plan view of a memory module according to an embodiment of the inventive concept;

FIG. 15 is a block diagram of a system according to an embodiment of the inventive concept; and

FIG. 16 is a block diagram of a memory card according to an embodiment of the inventive concept.

### DETAILED DESCRIPTION OF THE EMBODIMENTS

Hereinafter, the inventive concept will be described more fully with reference to the accompanying drawings, in which exemplary embodiments of the inventive concept are shown. Like reference numerals in the drawings denote like elements, and thus, their description will be omitted.

It will be appreciated that the inventive concept may be embodied in many different forms and should not be construed as being limited to the embodiments set forth herein; rather, these embodiments are provided so that this disclosure will be thorough and complete, and will fully convey the inventive concept to one of ordinary skill in the art.

It will be understood that, although the terms ‘first’, ‘second’, ‘third’, etc., may be used herein to describe various elements, regions, layers, sections, and/or components, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of the inventive concept. For example, a first component discussed below could be termed a second component, and similarly, a second component may be termed a first component without departing from the teachings of this disclosure.

Unless otherwise defined, all terms including technical and scientific terms used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

The operations of all methods described herein can be performed in any suitable order unless otherwise indicated herein or otherwise clearly contradicted by context. The inventive concept is not limited to the described order of the operations. For example, operations described herein as being consecutively performed may be simultaneously performed in practice, or may be executed in the opposite order to the described order.

Variations from the shapes of the illustrations as a result, for example, of manufacturing techniques and/or tolerances, are to be expected. Thus, embodiments of the inventive concept should not be construed as being limited to the particular shapes of regions illustrated herein but are to include deviations in shapes that result, for example, from manufacturing.

As used herein, the term “and/or” includes any and all combinations of one or more of the associated listed items. Expressions such as “at least one of,” when preceding a list of elements, modify the entire list of elements and do not modify the individual elements of the list.

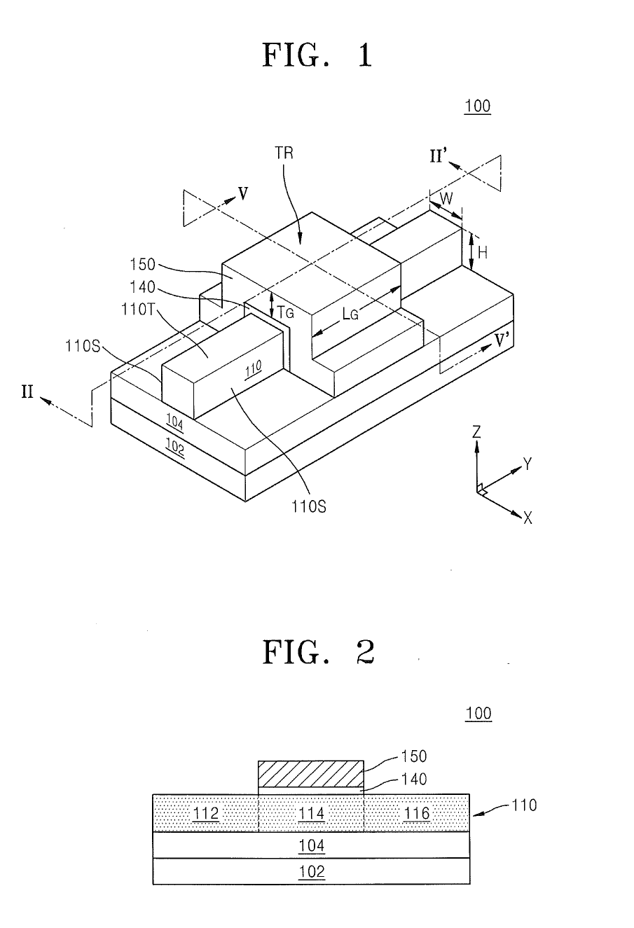

FIG. 1 is a partial perspective view of a semiconductor device 100 according to an embodiment of the inventive concept. The semiconductor device 100 includes a tri-gate transistor TR.

Referring to FIG. 1, the semiconductor device 100 includes a semiconductor body 110 that is disposed on an insulating layer 104. The semiconductor body 110 and the insulating layer 104 are both disposed on a substrate 102. The substrate 102 may be, for example, a semiconductor substrate or a semiconductor layer. The insulating layer 104 may include a buried oxide (BOX) layer.

The semiconductor body 110 may include at least one material selected from silicon (Si), germanium (Ge), SiC, SiGe, GaAs, GaP, InAs, InSb, InP, GaSb, GaAsP, AlInAs, AlGaAs, GaInAs, GaInP, and GaInAsP. In some embodiments, the semiconductor body 110 may include a monocrystalline layer having a crystalline direction <100> or <110> with respect to a direction (a Z-axis direction of FIG. 1) that is perpendicular to a lower surface of the substrate 102.

The semiconductor body 110 may extend in a first direction (a Y-axis direction of FIG. 1). The semiconductor body 110 has a fin-type structure having an upper surface 110T and opposite lateral walls 1105. The distance between the opposed lateral sidewalls 110S may define a width W of the semiconductor body 110. In some embodiments, the width W and a height H of the semiconductor body 110 are each equal to or less than 30 nm. For example, the width W and the height H of the semiconductor body 110 are each 20 nm. In some embodiments, the height H of the semiconductor body 110 is 0.5 to 2 times higher than the width W of the semiconductor body 110. In some embodiments, the width W and the height H of the semiconductor body 110 may be the same.

A gate dielectric layer 140 and a gate electrode 150 may extend on the insulating layer 104 and the semiconductor body 110 in a second direction (an X-axis direction of FIG. 1) that crosses the first direction. The gate electrode 150 may extend in a direction that is normal to a longitudinal direction of the semiconductor body 110. The gate dielectric layer 140 and the gate electrode 150 cover a portion of the upper surface 110T and the opposite lateral walls 110S of the semiconductor body 110.

The gate electrode 150 may have a thickness T_{G} of about 2 to about 20 nm and a gate length L_{G} of about 5 to about 30 nm.

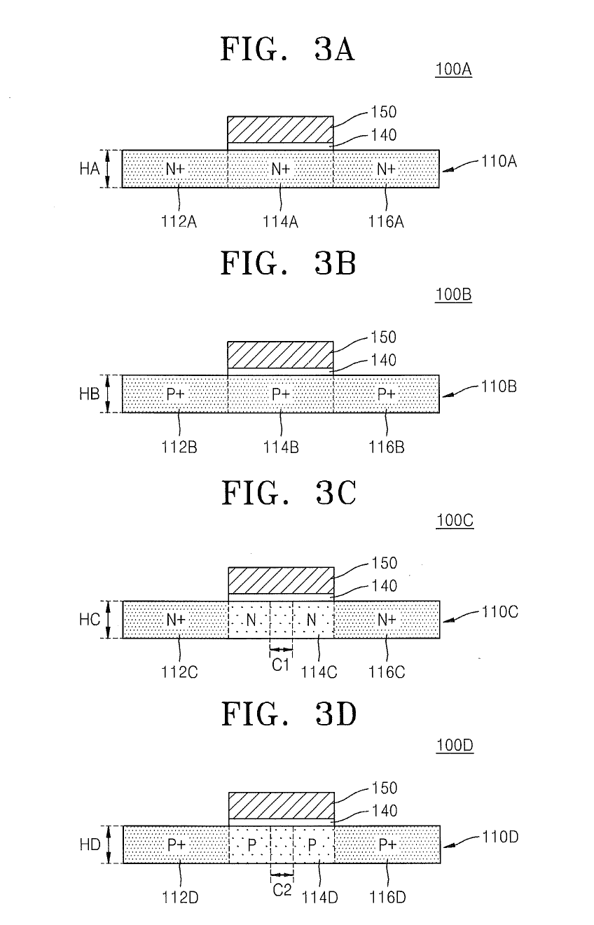

FIG. 2 is a cross-sectional view of the semiconductor device 100 taken along line II - II' of FIG. 1 according to an embodiment of the inventive concept.

Referring to FIGS. 1 and 2, the semiconductor body 110 includes a source region 112, a channel region 114, and a drain region 116 that are sequentially arranged and aligned in a longitudinal direction (a Y-axis direction of FIG. 1) and are doped with the same conductivity-type impurities. The semiconductor body 110 is doped with the same impurities across the source region 112, the channel region 114, and the drain region 116. Thus, a PN junction is not formed in the semiconductor body 110.

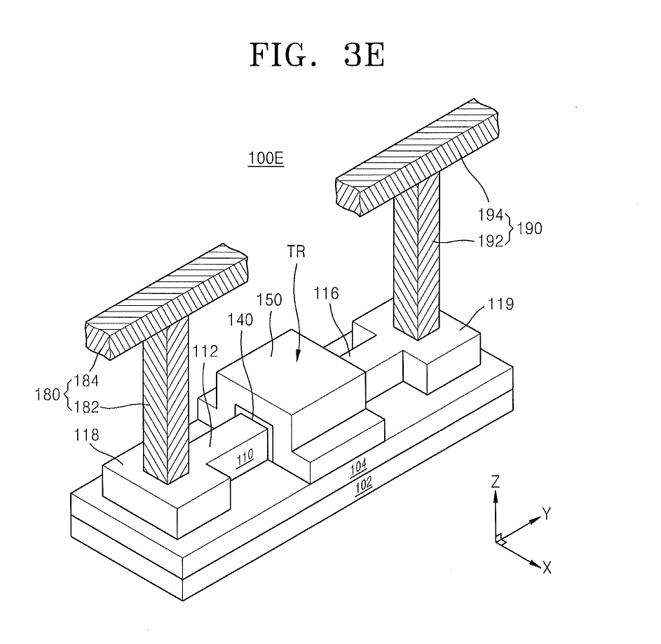

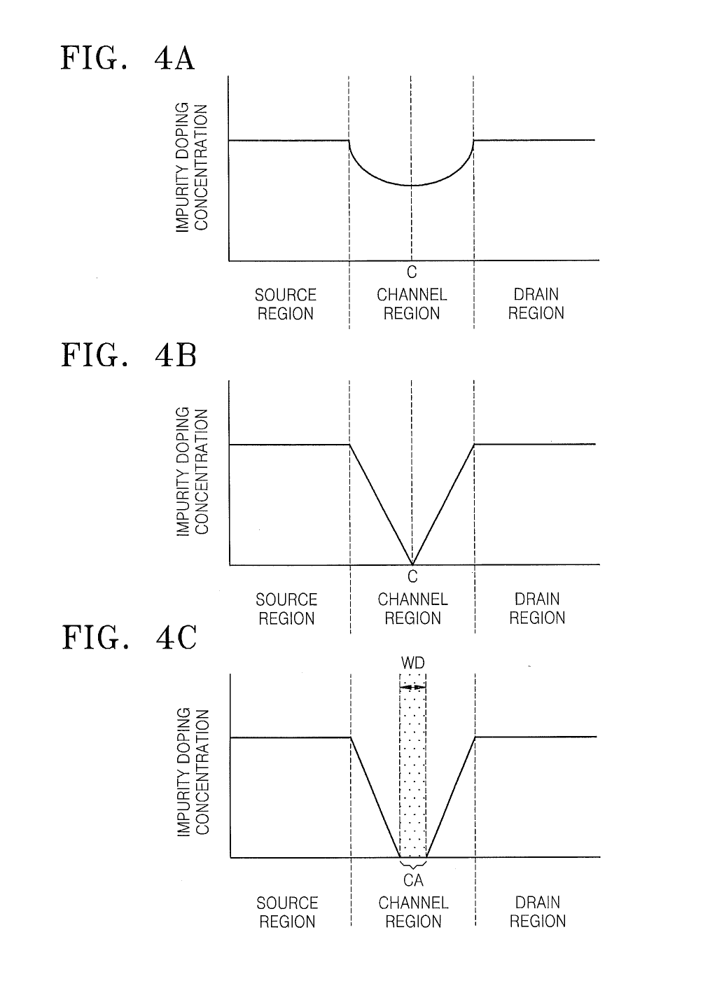

FIGS. 3A through 3D are cross-sectional views of some components of semiconductor devices 100A, 100B, 100C, and 100D according to embodiments of the inventive concept. FIGS. 3A through 3D show semiconductor bodies 110A, 110B, 110C, and 110D according to some embodiments of the inventive concept, which may be used as the semiconductor body 110 of the semiconductor device 100 shown in FIGS. 1 and 2. Like reference numerals in FIGS. 1, 2, and 3A through 3D denote like elements and their description is omitted for convenience of description.

Referring to FIG. 3A, in the semiconductor body 110A of the semiconductor device 100A, a source region 112A, a channel region 114A, and a drain region 116A are doped with N+ type impurities having a relatively high concentration (the “N+” designation indicates a relatively high doping concentration). The semiconductor body 110A may have a uniform impurity doping concentration across the source region 112A, the channel region 114A, and the drain region 116A. For example, the source region 112A, the channel region 114A, and the drain region 116A of the semiconductor body 110A may include N+type impurities having a doping concentration selected from a range of about 1×10²⁰ to about 1×10²³ atoms/cm³.

Referring to FIG. 3B, in the semiconductor body 110B of the semiconductor device 100B, a source region 112B, a channel region 114B, and a drain region 116B are doped with P+ type impurities having a relatively high concentration. The semiconductor body 110B may have a uniform impurity doping concentration across the source region 112B, the channel region 114B, and the drain region 116B. For example, the source region 112B, the channel region 114B, and the drain region 116B of the semiconductor body 110B may include P+ type impurities having a doping concentration selected from a range of about 1×10²⁰ to about 1×10²³ atoms/cm³.

When the semiconductor devices 110A and 110B shown in FIGS. 3A and 3B operate in an on-state or an off-state, a state between the source regions 112A and 112B and the respective drain regions 116A and 116B may be converted into a conductive state or an isolation state by the respective channel regions 114A and 114B. In particular, in an off-state, a charge carrier depletion region is formed in the channel regions 114A and 114B. In order to prevent a leakage current from being generated between the source regions 112A and 112B and the respective drain regions 116A and 116B and to improve on/off switching characteristics, the semiconductor bodies 110A and 110B may have heights HA and HB, respectively, that are equal to or less than about 20 nm to have a very thin structure, and a depletion region in which a charge carrier does not substantially exist may be formed in the channel regions 114A and 114B, in particular, a center region of the channel regions 114A and 114B below the gate electrode 150 when the gate electrode 150 is in an off-state.

Referring to FIG. 3C, in the semiconductor body 110C of the semiconductor device 100C, a source region 112C and a drain region 116C are doped with N+ type impurities having a relatively high concentration. The source region 112C and the drain region 116C may have a uniform impurity doping concentration across their entire areas. For example, the source region 112C and the drain region 116C of the semiconductor body 110C may include N+ type impurities having a doping concentration selected from a range of about 1×10²⁰ to about 1×10²³ atoms/cm³.

In the semiconductor body 110C, a channel region 114C that is doped with N-type impurities having a lower concentration than in the source region 112C and the drain region 116C is interposed between the source region 112C and the drain region 116C. The channel region 114C may have a doping concentration gradient in which an impurity concentration varies according to a position from the source region 112C and the drain region 116C to a center region C1 of the channel region 114C. A length of the center region C1, which is measured along a longitudinal direction of the semiconductor body 110C, may be determined in various ways.

Referring to FIG. 3D, in the semiconductor body 110D of the semiconductor device 100D, a source region 112D and a drain region 116D are doped with P+ type impurities having a relatively high concentration. The source region 112D and the drain region 116D may have a uniform impurity doping concentration across their entire areas. For example, the source region 112D and the drain region 116D of the semiconductor body 110D may include P+ type impurities having a doping concentration selected from a range of about 1×10²⁰ to about 1×10²³ atoms/cm³.

In the semiconductor body 110D, a channel region 114D that is doped with P-type impurities having a lower concentration than in the source region 112D and the drain region 116D is interposed between the source region 112D and the drain region 116D. The channel region 114D may have a doping concentration gradient in which an impurity concentration varies according to a position from the source region 112D and the drain region 116D to a center region C2 of the channel region 114D. A length of the center region C2, which is measured along a longitudinal direction of the semiconductor body 110D, may be determined in various ways.

In the semiconductor devices 100C and 100D shown in FIGS. 3C and 3D, the channel regions 114C and 114D may have an impurity doping concentration that increases toward the source regions 112C and 112D and the drain regions 116C and 116D and have a lowest impurity doping concentration in the center regions C1 and C2 of the channel regions 114C and 114D.

FIG. 3E is a perspective view of a semiconductor device 100E according to another embodiment of the inventive concept. Like reference numerals in FIGS. 1, 2, and 3E denote like elements and their description is omitted for convenience of description.

The semiconductor device 100E illustrated in FIG. 3E further includes first and second wiring structures 180 and 190 which may be used to apply a voltage to the source region 112 and the drain region 116, respectively. The semiconductor device 100E includes a first pad region 118 that is connected to the source region 112 of the semiconductor body 110 and a second pad region 119 that is connected to the drain region 116 of the semiconductor body 110. In some embodiments, the first pad region 118 and the second pad region 119 may be formed of the same material as that of the semiconductor body 110. In other embodiments, the first pad region 118 and the second pad region 119 may be formed of different materials from that of the semiconductor body 110.

The first wiring structure 180, which includes a source contact 182 and a first wiring 184, is connected to the first pad region 118. The first pad region 118 is electrically connected to the first wiring 184 through the source contact 182. The second wiring structure 190, which includes a drain contact 192 and a second wiring 194, is connected to the second pad region 119. The second pad region 119 is electrically connected to the second wiring 194 through the drain contact 192. A gate voltage may be applied to the gate electrode 150 through a contact pad (not shown) that is connected to the gate electrode 150.

The configurations and materials of the first pad region 118 and the second pad region 119 are referred to with respect to the description of the semiconductor body 110 described with reference to FIGS. 1 and 2. In some embodiments, the first wiring structure 180 and the second wiring structure 190 are formed of metal. For example, the first wiring structure 180 and the second wiring structure 190 may include at least one metal selected from titanium (Ti), tantalum (Ta), tungsten (W), copper (Cu), and aluminum (Al). In other embodiments, the first wiring structure 180 and the second wiring structure 190 may further include at least one metal compound selected from TiN, TaN, and WN in order to improve, for example, adhesive properties, structural stability, and/or electrical properties.

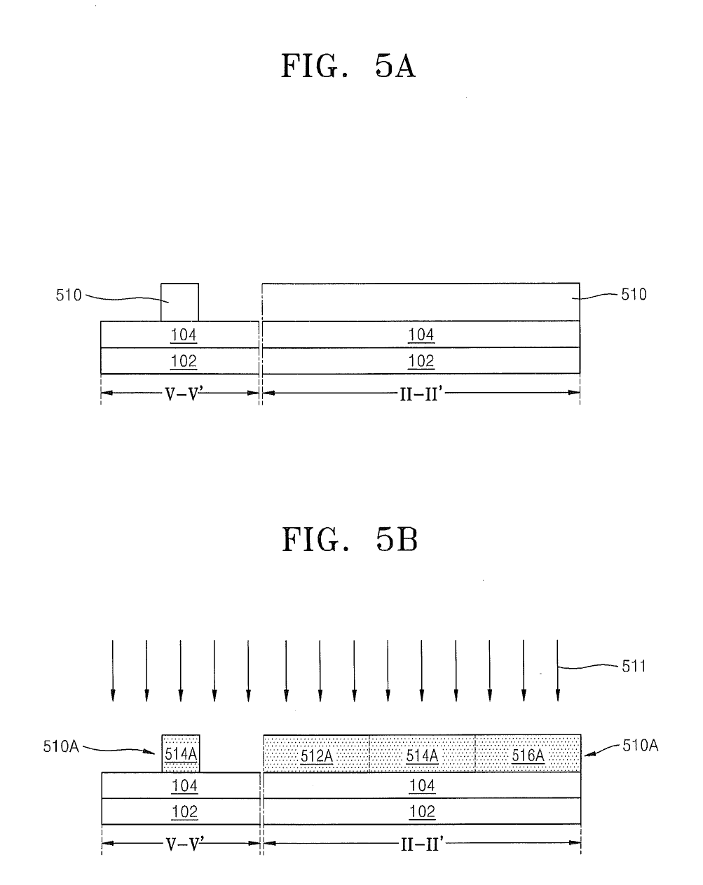

FIGS. 4A through 4C are graphs showing impurity doping gradients in the channel regions 114C and 114D of the semiconductor devices 100C and 100D shown in FIGS. 3C and 3D, according to embodiments of the inventive concept.

Referring to FIG. 4A, the channel regions 114C and 114D have an impurity doping concentration that increases toward the source regions 112C and 112D and the drain regions 116C and 116D and have a lowest impurity doping concentration in a center region (indicated by “C” in FIG. 4A) of the channel regions 114C and 114D.

Referring to FIG. 4B, the channel regions 114C and 114D have an impurity doping concentration that increases toward the source regions 112C and 112D and the drain regions 116C and 116D and decreases toward a center region (indicated by “C” in FIG. 4B) of the channel regions 114C and 114D. In this case, an impurity concentration of the center region C of the channel regions 114C and 114D may be substantially 0 atoms/cm³ or may be substantially undoped.

Referring to FIG. 4C, in the channel regions 114C and 114D, a depletion region in which a charge carrier does not substantially exist may be formed over a predetermined width WD in a center region (indicated by “CA” in FIG. 4C) between the source regions 112C and 112D and the drain regions 116C and 116D.

Referring back to FIGS. 1 and 2, in some embodiments, the gate dielectric layer 140 may include a high dielectric layer having a higher dielectric constant than a silicon oxide layer. For example, the gate dielectric layer 140 may have a dielectric constant of about 10 to about 25. In some embodiments, the gate dielectric layer 140 may be formed of at least one material selected from hafnium oxide (HfO), hafnium silicon oxide (HfSiO), hafnium oxynitride (HfON), hafnium silicon oxynitride (HfSiON), lanthanum oxide (LaO), lanthanum aluminium oxide (LaAlO), zirconium oxide (ZrO), zirconium silicon oxide (ZrSiO), zirconium oxynitride (ZrON), zirconium silicon oxynitride (ZrSiON), tantalum oxide (TaO), titanium oxidy (TiO), barium strontium titanium oxide (BaSrTiO), barium titanium oxide (BaTiO), strontium titanium oxide (SrTiO), yttrium oxide (YO), aluminium oxide (AlO), and lead scandium tantalum oxide (PbScTaO). In some embodiments, the gate dielectric layer 140 may include a high dielectric layer, a silicon oxide layer, a silicon nitride layer, a silicon oxynitride layer, or a combination thereof. In some embodiments, the gate dielectric layer 140 may be formed via atomic layer deposition (ALD).

The gate electrode 150 may include at least one selected from metal, metal nitride, and metal carbide. In some embodiments, the gate electrode 150 may include at least one selected from tungsten (W), titanium (Ti), tantalum (Ta), ruthenium (Ru), platinum (Pt), gold (Au), silver (Ag), hafnium (Hf), zirconium (Zr), aluminum (Al), palladium (Pd), cobalt (Co), nickel (Ni), iridium (Ir), molybdenum (Mo), nitrides thereof, and carbides thereof.

As shown in FIGS. 3A and 3C, when the semiconductor bodies 110A and 110C are doped with N-type impurities, an NMOS transistor is embodied by the semiconductor devices 100A and 100C. In this case, in some embodiments, the gate electrode 150 may include a work function metal layer formed of hafnium (Hf), zirconium (Zr), titanium (Ti), tantalum (Ta), aluminum (Al), or a combination thereof. In other embodiments, the gate electrode 150 includes a work function metal layer formed of at least one selected from HfC, TaC, TiC, TiN, TaN, TaTbN, TaErN, TaYbN, RuTa, and NiTa. In still other embodiments, the gate electrode 150 includes a work function metal layer formed of TiAl nitride or TaAl nitride. In the semiconductor devices 100A and 100C, the work function metal layer of the gate electrode 150 may provide a work function of about 4.1 to about 4.5 eV.

As shown in FIGS. 3B and 3D, when the semiconductor bodies 110B, 110D are doped with P-type impurities, a PMOS transistor is embodied by the semiconductor devices 100B and 100D. In this case, in some embodiments, the gate electrode 150 includes a work function metal layer formed of ruthenium (Ru), palladium (Pd), platinum (Pt), cobalt (Co), nickel (Ni), iridium (Ir), molybdenum (Mo), HfRu, or a combination thereof. In other embodiments, the gate electrode 150 includes a work function metal layer formed of at least one selected from TiN, WN, TaN, RuN, TiAlN, TaAlN, and TiCN. In the semiconductor devices 100B and 100D, the work function metal layer of the gate electrode 150 may provide a work function of about 4.8 to about 5.2 eV.

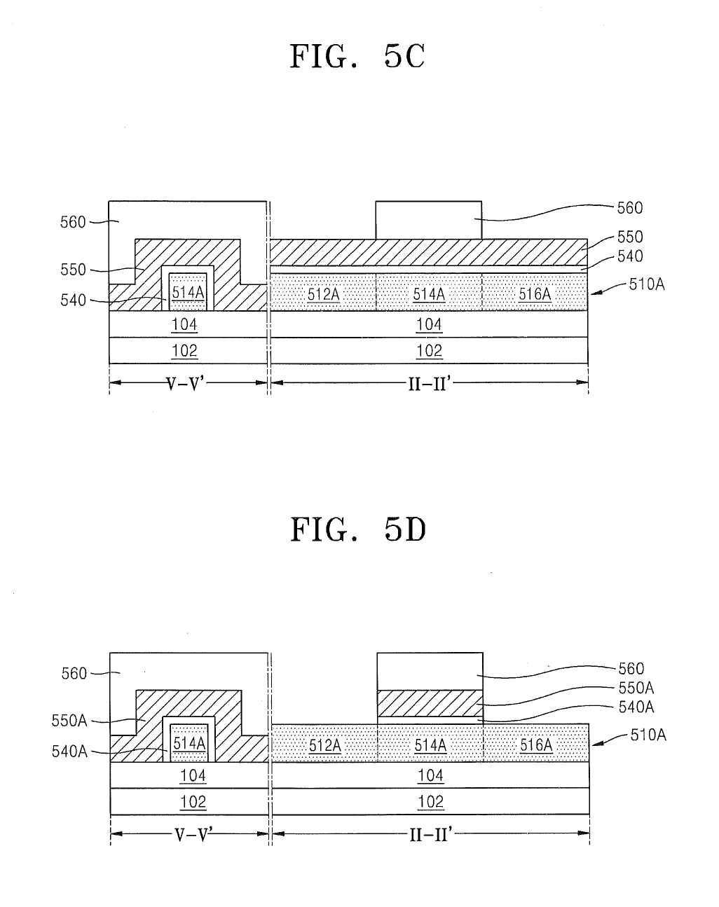

FIGS. 5A through 5D are cross-sectional views taken along line II-II′ of FIG. 1 and line V-V′ of FIG. 1 showing sequential processes of a method of manufacturing a semiconductor device according to an embodiment of the inventive concept. FIGS. 5A and 5D show a method of manufacturing a semiconductor device that has a semiconductor body in which a high-concentration of dopants having the same conductivity type are diffused to have a uniform doping concentration in a source region, a channel region, and a drain region, like the semiconductor devices 100A and 100B shown in FIGS. 3A and 3B. Like reference numerals in FIGS. 1 through 3D and 5A through 5D denote like elements and a repeated description thereof is not provided.

Referring to FIG. 5A, an insulating layer 104 is formed on a substrate 102, and a fin-type active region 510 is formed on an insulating layer 104.

In some embodiments, in order to form the fin-type active region 510, a silicon on insulator (SOI) substrate on which the substrate 102, the insulating layer 104, and a silicon layer (not shown) are sequentially stacked may be prepared and then the silicon layer may be patterned by using an etch method such as a photolithography method and a reactive ion etching (RIE) method.

Referring to FIG. 5B, a dopant 511 of a single conductivity type is injected into an entire region of the fin-type active region 510 via, for example, ion implantation and the resultant structure is heat-treated to activate impurity ions, thereby forming a semiconductor body 510A doped with a high concentration of impurities.

For example, the dopant 511 including N type impurity ions may be injected into the fin-type active region 510 to form the semiconductor body 510A including a source region 512A, a channel region 514A, and a drain region 516A, which each include an N+ type doping region. In other embodiments, the dopant 511 including P type impurity ions may be injected into the fin-type active region 510 to form the semiconductor body 510A including the source region 512A, the channel region 514A, and the drain region 516A, which each include a P+ type doping region.

Referring to FIG. 5C, a gate dielectric material layer 540 and a gate electrode layer 550 including metal are sequentially formed on the semiconductor body 510A, and a hard mask pattern 560 is formed on the gate electrode layer 550 to cover the channel region 514A.

The configurations and materials of the semiconductor body 510A, the gate dielectric material layer 540, and the gate electrode layer 550 can be referred to with respect to the descriptions of the semiconductor body 110, the gate dielectric layer 140, and the gate electrode 150 described with reference to FIGS. 1 and 2. The gate dielectric material layer 540 and the gate electrode layer 550 may be formed, for example, via ALD or chemical vapor deposition (CVD).

Referring to FIG. 5D, the gate electrode layer 550 and the gate dielectric material layer 540 are sequentially etched by using the hard mask pattern 560 as an etch mask to form a gate dielectric layer 540A and a gate electrode 550A. Then, the hard mask pattern 560 is removed.

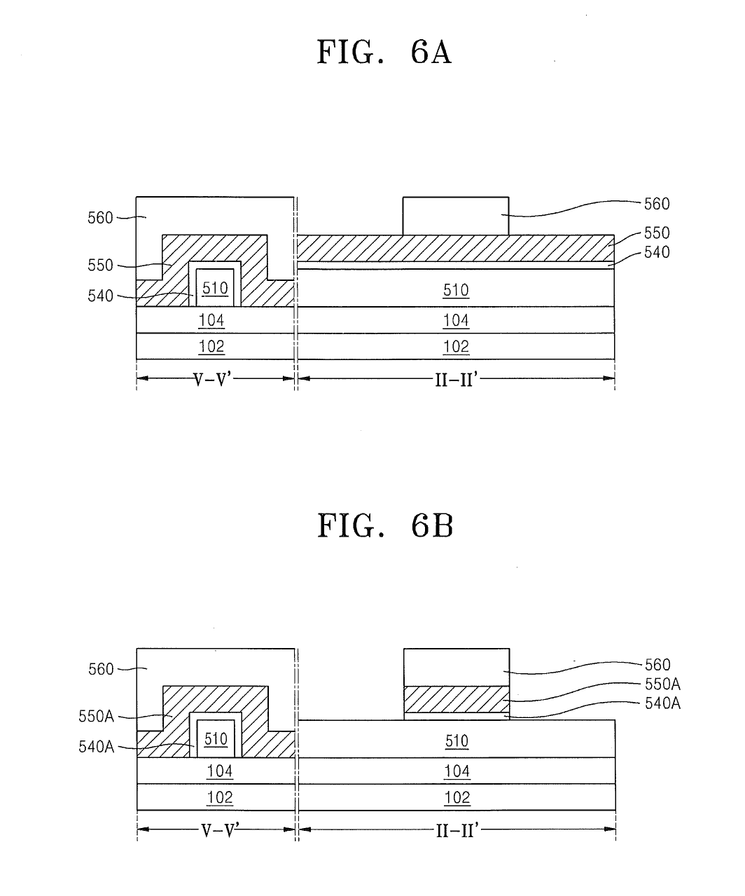

FIGS, 6A through 6E are cross-sectional views taken along line II-II′ of FIG. 1 and line V-V′ of FIG. 1 showing sequential processes of a method of manufacturing a semiconductor device according to another embodiment of the inventive concept. FIGS. 6A through 6E show a method of manufacturing a semiconductor device including a semiconductor body in which a source region, a channel region, and a drain region have dopants having the same conductivity type. A high-concentration of dopants are diffused in the source region and the drain region, while the channel region has a doping concentration gradient, like the semiconductor devices 100C and 100D shown in FIGS. 3C and 3D. Like reference numerals in FIGS. 1 through 5D and 6A through 6E denote like elements and a repeated description thereof is not provided.

Referring to FIG. 6A, an insulating layer 104 is formed on a substrate 102, and a fin-type active region 510 is formed on the insulating layer 104. A gate dielectric material layer 540 and a gate electrode layer 550 including metal are sequentially formed on the fin-type active region 510 by using the method described with reference to FIG. 5A. Then, the hard mask pattern 560 is formed on the gate electrode layer 550 to cover a portion of the fin-type active region 510 in which a channel region is to be formed.

Referring to FIG. 6B, the gate electrode layer 550 and the gate dielectric material layer 540 are sequentially etched using the hard mask pattern 560 as an etch mask to expose an upper surface of the fin-type active region 510 around the hard mask pattern 560, and the gate dielectric layer 540A and the gate electrode 550A are formed on a portion of the fin-type active region 510 to cover an upper surface and opposite lateral surfaces of the fin-type active region 510 by using the method described with reference to FIG. 5D.

Referring to FIG. 6C, a dopant 620 including single conductivity-type impurity ions is injected into the fin-type active region 510 using the hard mask pattern 560 as an ion injection mask to form a source region 612A and a drain region 616A at opposite sides of the gate electrode 550A on the fin-type active region 510.

In some embodiments, when the dopant 620 includes N type impurity ions, the source region 612A and the drain region 616A, which include an N+ type doping region, may be formed. In other embodiments, when the dopant 620 includes P type impurity ions, the source region 612A and the drain region 616A, which include a P+type doping region, may be formed. The source region 612A and the drain region 616A may have a doping concentration selected from a range of about 1×10²⁰ to about 1×10²³ atoms/cm³.

Referring to FIG. 6D, the resultant structure including the source region 612A and the drain region 616A is heat-treated to diffuse dopants from the source region 612A and the drain region 616A into the fin-type active region 510 between the source region 612A and the drain region 616A. Thus, a channel region 614A having a doping concentration gradient is formed below the gate electrode 550A on the fin-type active region 510.

The channel region 614A has a doping concentration gradient in which an impurity concentration varies according to a position from the source region 612A and the drain region 616A to a center region of the channel region 614A. For example, the channel region 614A may have a doping concentration gradient according to any one of the examples shown in FIGS. 4A through 4C.

In order to form the channel region 614A, the structure may be heat treated at a temperature of about 850 to about 1100° C. for about 1 second to about 3 minutes to diffuse dopants in the source region 612A and the drain region 616A to the fin-type active region 510 between the source region 612A and the drain region 616A. For example, the heat treatment may be performed at a temperature of about 1000° C. for about 10 seconds, or alternatively, may be performed at a temperature of about 850° C. for about 2 minutes. The heat treatment may be performed in an atmosphere containing argon (Ar) and nitrogen (N).

Referring to FIG. 6E, the hard mask pattern 560 that was used as an ion injection mask is removed to expose an upper surface of the gate electrode 550A.

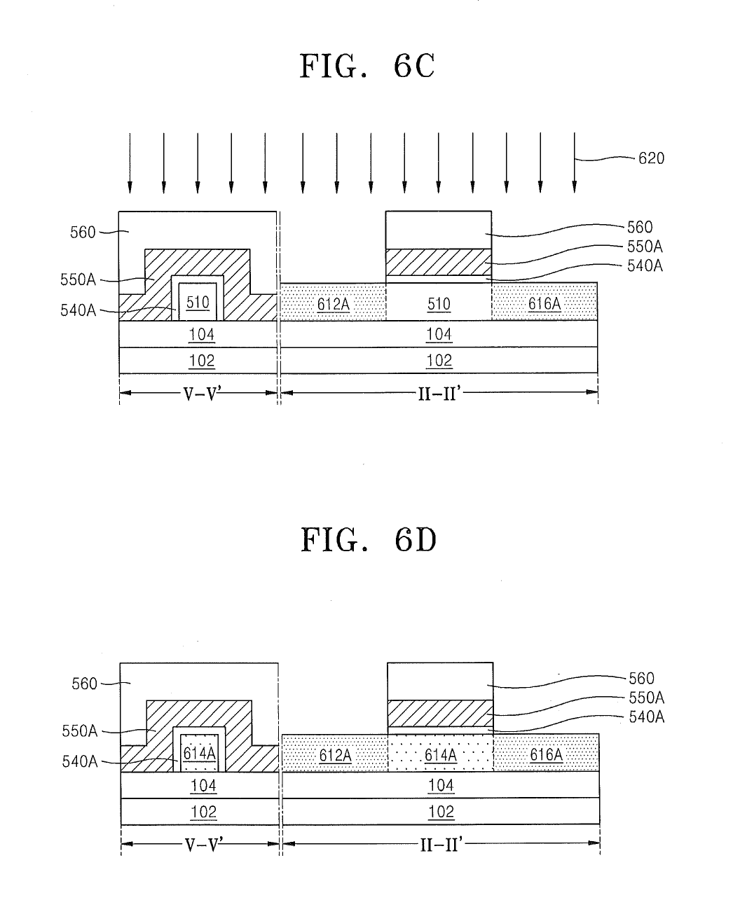

FIGS. 7A through 7C are cross-sectional views taken along line II-II′ of FIG. 1 and line V-V′ of FIG. 1 showing sequential processes of a method of manufacturing a semiconductor device 200 (see FIG. 7C), according to another embodiment of the inventive concept. In FIGS. 7A through 7C, a gate dielectric layer 740A and a gate electrode 750A (refer to FIG. 7C) having different structures from those of the gate dielectric layer 140 and the gate electrode 150 shown in FIGS. 1 and 2 are formed. Like reference numerals in FIGS. 1 through 6E and 7A through 7C denote like elements and a repeated description thereof is not provided.

Referring to FIG. 7A, the semiconductor body 510A doped with high concentration impurities of a single conductivity type is formed on the insulating layer 104, and then a plurality of insulating patterns 730 are formed to cover the source region 512A and the drain region 516A so as to expose the channel region 514A of the semiconductor body 510A by using the method described with reference to FIGS. 5A and 5B.

The insulating patterns 730 define a gate space GS in which the gate dielectric layer 740A and the gate electrode 750A (refer to FIG. 7C) are to be formed. According to the present embodiment, an upper surface 514T and opposite lateral walls 514S of the channel region 514A and an upper surface 104T of the insulating layer 104 adjacent to the channel region 514A are exposed through the insulating patterns 730 in the gate space GS.

Referring to FIG. 7B, a gate dielectric material layer 740 is formed to a uniform thickness to cover the exposed surface of the insulating patterns 730 and the upper surface 514T and the opposite lateral walls 514S (refer to FIG. 7A) of the channel region 514A, which are exposed through the insulating patterns 730. Then, a gate electrode layer 750 is formed on the gate dielectric material layer 740 to fill the gate space GS.

The configurations and materials of the gate dielectric material layer 740 and the gate electrode layer 750 can be referred to with respect to the description of the gate dielectric layer 140 and the gate electrode 150 described with reference to FIGS. 1 and 2. An ALD method or a CVD method may be used to form the gate dielectric material layer 740 and the gate electrode layer 750.

Referring to FIG. 7C, portions of the gate dielectric material layer 740 and the gate electrode layer 750 which are on the insulating patterns 730 are removed so that the gate dielectric material layer 740 and the gate electrode layer 750 remain only in the gate space GS (refer to FIG. 7B), thereby forming a gate dielectric layer 740A and a gate electrode 750A in the gate space GS (refer to FIG. 7B) and upper surfaces of the insulating patterns 730 around the gate dielectric layer 740A and the gate electrode 750A are exposed. The selected portions of the gate dielectric material layer 740 and the gate electrode layer 750 may be removed using, for example, a chemical mechanical polishing (CMP) method or an etch-back method.

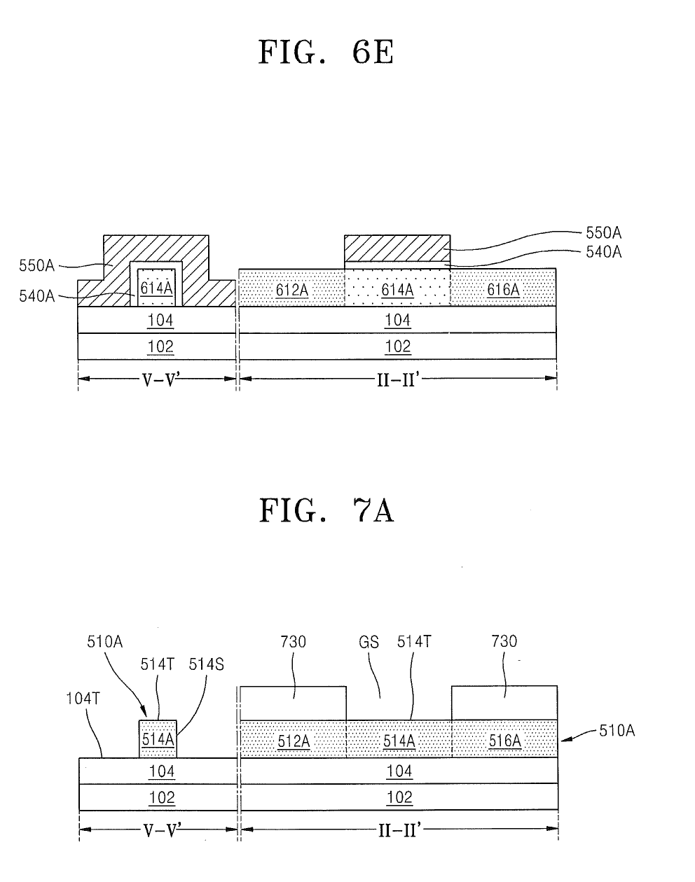

FIGS. 8A through 8C are diagrams of a semiconductor device 300 according to an embodiment of the inventive concept. FIG. 8A is a plan view of the semiconductor device 300, FIG. 8B is a cross-sectional view of the semiconductor device 300 taken along line 8B1-8B1′ and line 8B2-8B2′ of FIG. 8A, and FIG. 8C is a cross-sectional view of the semiconductor device 300 taken along line 8C1-8C1′ and line 8C2-8C2′ of FIG. 8A.

Like reference numerals in FIGS. 1 through 3D and 8A through 8C denote like elements and their description is omitted for convenience of description.

Referring to FIGS. 8A through 8C, the substrate 102 of the semiconductor device 300 includes a first metal oxide semiconductor (MOS) region 1ST MOS REGION and a second MOS region 2ND MOS REGION. A plurality of fin-type semiconductor bodies 810A and 810B (refer to FIG. 8B) are formed on an insulating layer 104 that is formed on a substrate 102. The fin-type semiconductor bodies 810A and 810B include the first semiconductor body 810A formed in the first MOS region 1ST MOS REGION and the second semiconductor body 810B formed in the second MOS region 2ND MOS REGION, respectively. In FIGS. 8A through 8C, the first semiconductor body 810A and the second semiconductor body 810B extend parallel to each other in one direction (a Y-axis direction in FIG. 8A), in the first MOS region 1ST MOS REGION and the second MOS region 2ND MOS REGION, but the inventive concept is not limited thereto. Thus, in other embodiments the first semiconductor body 810A and the second semiconductor body 810B may extend in different directions in the first MOS region 1ST MOS REGION and the second MOS region 2ND MOS REGION.

In FIGS. 8A through 8C, a first MOS transistor TR1, including the first semiconductor body 810A, a first gate dielectric layer 840A, and a first gate electrode 850A, is formed in the first MOS region 1ST MOS REGION. A second MOS transistor TR2, including the second semiconductor body 810B, a second gate dielectric layer 840B, and a second gate electrode 850B, is formed in the second MOS region 2ND MOS REGION. FIGS. 8A through 8C show a case where the first MOS transistor TR1 is an NMOS transistor and the second MOS transistor TR2 is a PMOS transistor.

In the first MOS region 1ST MOS REGION, the first semiconductor body 810A includes a first source region 812A, a first channel region 814A, and a first drain region 816A, which are doped with N+ type impurities having a high concentration. The first semiconductor body 810A may have a uniform impurity doping concentration across the first source region 812A, the first channel region 814A, and the first drain region 816A. For example, the first source region 812A, the first channel region 814A, and the first drain region 816A may each have a doping concentration selected from a range of about 1×10²⁰ to about 1×10²³ atoms/cm³.

In the second MOS region 2ND MOS REGION, the second semiconductor body 810B includes a second source region 812B, a second channel region 814B, and a second drain region 816B, which are doped with P+ type impurities having a high concentration. The second semiconductor body 810B may have a uniform impurity doping concentration across the second source region 812B, the second channel region 814B, and the second drain region 816B. For example, the second source region 812B, the second channel region 814B, and the second drain region 816B may each have a doping concentration selected from a range of about 1×10²⁰ to about 1×10²³ atoms/cm³.

In the first MOS region 1ST MOS REGION, the first gate electrode 850A extends in a direction (an X-axis direction in FIG. 8A) that crosses the first semiconductor body 810A to cover an upper surface and opposite lateral surfaces of the first semiconductor body 810A. The first gate electrode 850A includes a first metal including at least one selected from metal, metal nitride, and metal carbide. In some embodiments, the first metal of the first gate electrode 850A includes at least one of W, Ti, Ta, Ru, Pt, Au, Ag, Hf, Zr, Al, Pd, Co, Ni, Ir, Mo, nitrides thereof, and carbides thereof. In some embodiments, the first gate electrode 850A includes a first work function metal layer including Hf, Zr, Ti, Ta, Al, or a combination thereof. In other embodiments, the first gate electrode 850A includes a first work function metal layer including at least one selected from HfC, TaC, TiC, TiN, TaN, TaTbN, TaErN, TaYbN, RuTa, and NiTa. In still other embodiments, the first gate electrode 850A includes a first work function metal layer including TiAl nitride or TaAl nitride. The first work function metal layer of the first gate electrode 850A may provide a work function of about 4.1 to about 4.5 eV. The first gate dielectric layer 840A is interposed between the first semiconductor body 810A and the first gate electrode 850A.

In the second MOS region 2ND MOS REGION, the second gate electrode 850B extends in a direction (an X-axis direction in FIG. 8A) that crosses the second semiconductor body 810B to cover an upper surface and opposite lateral surfaces of the second semiconductor body 810B. The second gate electrode 850B includes a second metal that is different from the first metal. The second metal includes at least one selected from metal, metal nitride, and metal carbide. In some embodiments, the second metal of the second gate electrode 850B includes at least one selected from W, Ti, Ta, Ru, Pt, Au, Ag, Hf, Zr, Al, Pd, Co, Ni, Ir, Mo, nitrides thereof, and carbides thereof. In some embodiments, the second gate electrode 850B includes a second work function metal layer including Ru, Pd, Pt, Co, Ni, Ir, Mo, HfRu, or a combination thereof. In other embodiments, the second gate electrode 850B includes a second work function metal layer including at least one selected from TiN, WN, TaN, RuN, TiAlN, TaAlN, and TiCN. The second work function metal layer of the second gate electrode 850B may provide a work function of about 4.8 to about 5.2 eV. The second gate dielectric layer 840B is interposed between the second semiconductor body 810B and the second gate electrode 850B.

The description of the first gate dielectric layer 840A and the second gate dielectric layer 840B can be referred to with respect to the description of the gate dielectric layer 140 described with reference to FIGS. 1 and 2.

It would be understood by one of ordinary skill in the art that the semiconductor device 300 described with reference to FIGS. 8A through 8C may be manufactured via the method of manufacturing a semiconductor device which is described above with reference to FIGS. 5A through 5D.

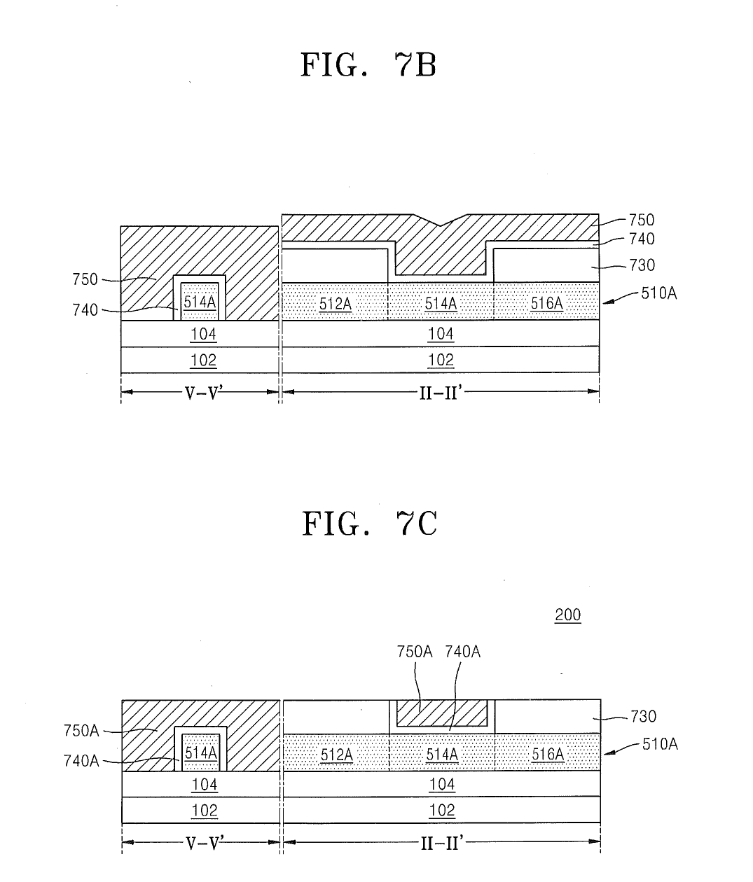

FIG. 9 is a cross-sectional view of a semiconductor device 400 according to another embodiment of the inventive concept.

The configuration of the semiconductor device 400 is substantially the same as the configuration of the semiconductor device 300 shown in FIGS. 8A through 8C. However, the semiconductor device 400 is configured such that a source region, a channel region, and a drain region have dopants having the same conductivity type, where a high-concentration of dopants are diffused in the source region and the drain region, and the channel region has a doping concentration gradient, in the first MOS region 1ST MOS REGION and the second MOS region 2ND MOS REGION, like the semiconductor devices 100C and 100D shown in FIGS. 3C and 3D. Like reference numerals in FIGS. 1 through 8C and 9 denote like elements and their description is omitted for convenience of description.

Referring to FIG. 9, a first MOS transistor TR3, including a first semiconductor body 910A, the first gate dielectric layer 840A, and the first gate electrode 850A, is formed in the first MOS region 1ST MOS REGION of the semiconductor device 400. A second MOS transistor TR4, including a second semiconductor body 910B, the second gate dielectric layer 840B, and the second gate electrode 850B, is formed in the second MOS region 2ND MOS REGION.

In the first semiconductor body 910A, a first source region 912A and a first drain region 916A are doped with N+ type impurities having a high concentration. A first channel region 914A has a doping concentration gradient in which an impurity concentration varies according to a position from the first source region 912A and the first drain region 916A to a central portion of the first channel region 914A. The first channel region 914A may have a doping concentration gradient according to any one of the examples shown in FIGS. 4A through 4C. The description of the first channel region 914A may be referred to with respect to the description of the channel region 114C described with reference to FIG. 3C.

In the second semiconductor body 910B, a second source region 912B and a second drain region 916B are doped with P+ type impurities having a high concentration. A second channel region 914B has a doping concentration gradient in which an impurity concentration varies according to a position from the second source region 912B and the second drain region 916B to a center region of the second channel region 914B. The second channel region 914B may have a doping concentration gradient according to any one of the examples shown in FIGS. 4A through 4C. The description of the second channel region 914B may be referred to with respect to the description of the channel region 114D described with reference to FIG. 3D.

It will be understood by one of ordinary skill in the art that the semiconductor device 400 described with reference to FIG. 9 may be manufactured via the method of manufacturing a semiconductor device which is described with reference to FIGS. 6A through 6E.

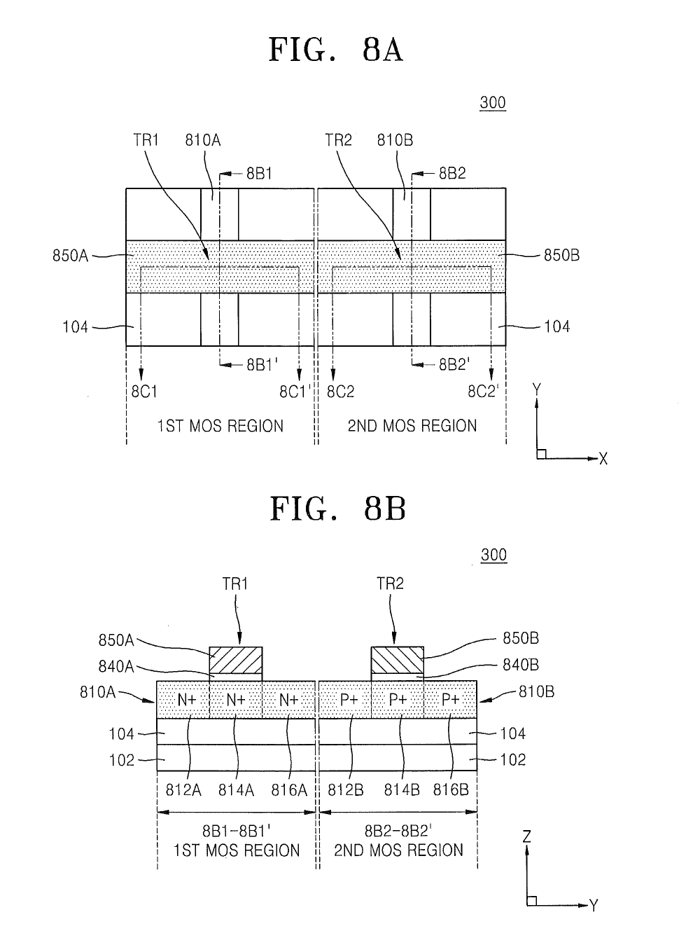

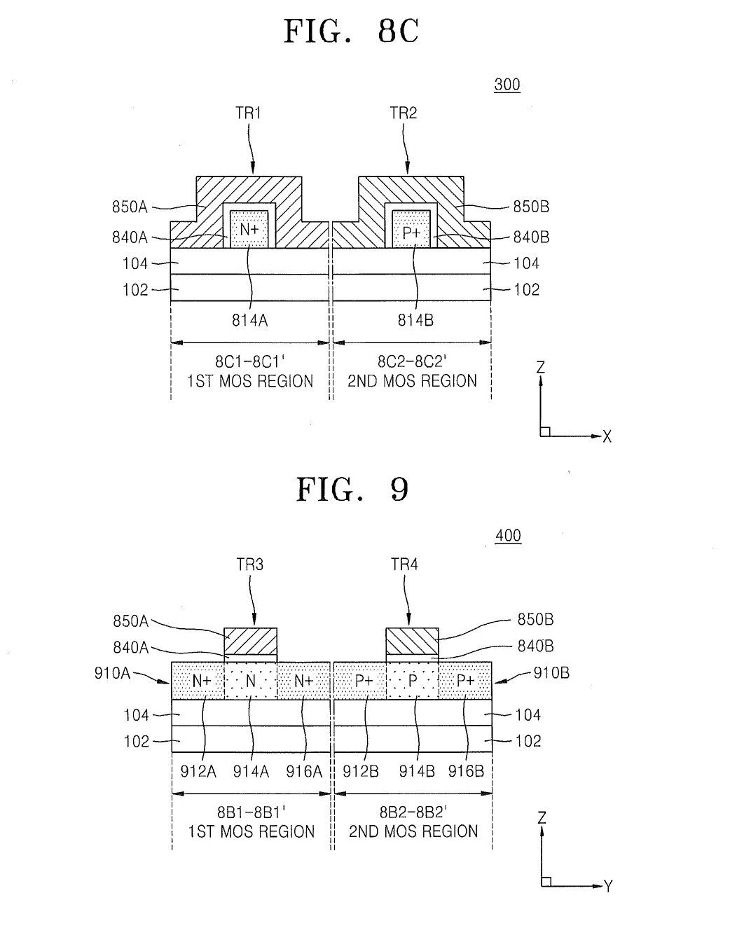

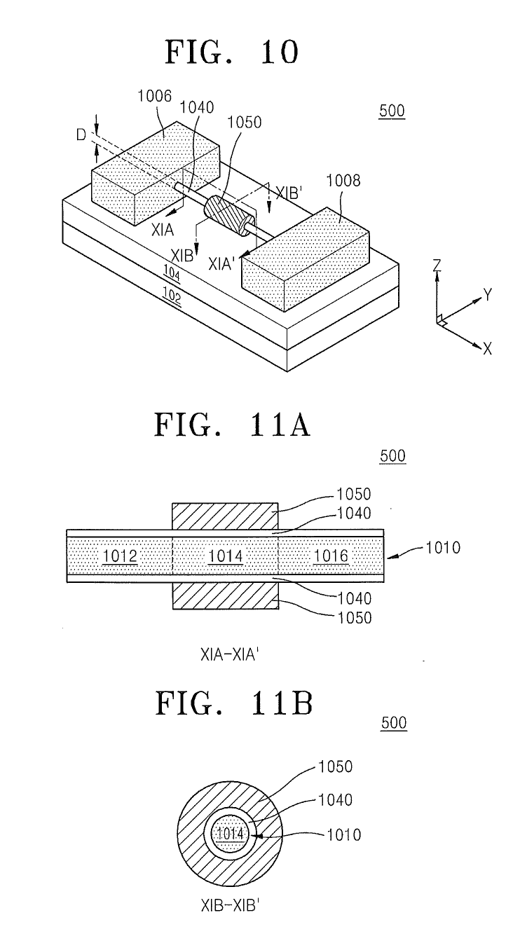

FIG. 10 is a perspective view of a semiconductor device 500 according to another embodiment of the inventive concept. FIG. 11A is a cross-sectional view of the semiconductor device 500 taken along line XIA-XIA′ of FIG. 10. FIG. 11B is a cross-sectional view of the semiconductor device 500 taken along line XIB-XIB′ of FIG. 10. Like reference numerals in FIGS. 10, 11A and 11B denote like elements and a repeated description thereof is not provided.

Referring to FIGS. 10, 11A, and 11B, the semiconductor device 500 includes a first pad region 1006 and a second pad region 1008, which are disposed on an insulating layer 104 that is formed on a substrate 102. The first pad region 1006 and the second pad region 1008 are connected to each other through a semiconductor body 1010 (refer to FIG. 11A) having a nanowire shape. The semiconductor body 1010 extends in a first direction (an X-axis direction in FIG. 10) between the first pad region 1006 and the second pad region 1008.

The first pad region 1006 and the second pad region 1008 may be integrated with the semiconductor body 1010. The configurations and materials of the first pad region 1006, the second pad region 1008, and the semiconductor body 1010 are referred to with respect to the description of the semiconductor body 110 described above with reference to FIGS. 1 and 2.

In some embodiments, the semiconductor body 1010 may have a diameter D equal to or less than about 30 nm. For example, the semiconductor body 1010 may have a diameter D equal to or less than about 20 nm. It will be appreciated that the semiconductor body 1010 may have a cross-section other than a circular cross-section such as, for example, an oval cross-section or a rectangular cross-section.

The semiconductor body 1010 includes a source region 1012, a channel region 1014, and a drain region 1016 that are sequentially arranged and aligned in a longitudinal direction (an X-axis direction in FIG. 10) and are doped with the same conductivity type impurities.

The semiconductor device 500 includes a gate dielectric layer 1040 surrounding the semiconductor body 1010, and a gate electrode 1050 covering the channel region 1014 across the gate dielectric layer 1040. The gate electrode 1050 surrounds the channel region 1014 portion of the semiconductor body 1010. The configurations and materials of the gate dielectric layer 1040 and the gate electrode 1050 can be referred to with respect to the descriptions of the gate dielectric layer 140 and the gate electrode 150 described with reference to FIGS. 1 and 2.

The same conductivity type impurities are doped in the semiconductor body 1010 across the source region 1012, the channel region 1014, and the drain region 1016. Accordingly, a PN junction is not formed in the semiconductor body 1010.

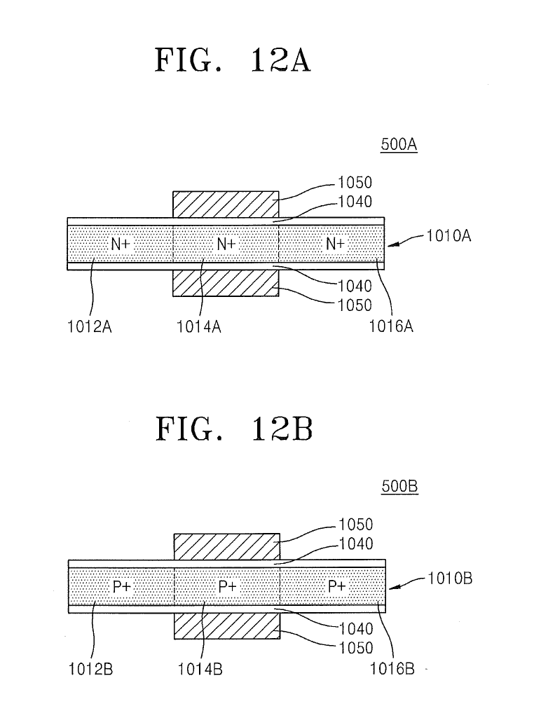

FIGS. 12A through 12D are cross-sectional views of semiconductor devices 500A, 500B, 500C, and 500D according to embodiments of the inventive concept. FIGS. 12A through 12D show semiconductor bodies 1010A, 1010B, 1010C, and 1010D according to some embodiments of the inventive concept, which may be used as the semiconductor body 1010 of the semiconductor device 500 shown in FIGS. 10, 11A, and 11B. Like reference numerals in FIGS. 10, 11A, 11B, and FIGS. 12A through 12D denote like elements and their description is omitted for convenience of description.

Referring to FIG. 12A, in the semiconductor body 1010A of the semiconductor device 500A, a source region 1012A, a channel region 1014A, and a drain region 1016A are doped with N+ type impurities having a high concentration. The descriptions of the source region 1012A, the channel region 1014A, and the drain region 1016A can be referred to with respect to the descriptions of the source region 112A, the channel region 114A, and the drain region 116A described above with reference to FIG. 3A.

Referring to FIG. 12B, in the semiconductor body 1010B of the semiconductor device 500B, a source region 1012B, a channel region 1014B, and a drain region 1016B are doped with P+type impurities having a high concentration. The descriptions of the source region 1012B, the channel region 1014B, and the drain region 1016B can be referred to with respect to the descriptions of the source region 112B, the channel region 114B, and the drain region 116B described above with reference to FIG. 3B.

Referring to FIG. 12C, in the semiconductor body 1010C of the semiconductor device 500C, a source region 1012C and a drain region 1016C are doped with N+ type impurities having a high concentration. In the semiconductor body 1010C, a channel region 1014C that is between the source region 1012C and the drain region 1016C is doped with N-type impurities and includes a region having a lower impurity doping concentration than that in the source region 1012C and the drain region 1016C. The channel region 1014C has a doping concentration gradient in which an impurity concentration various according to a position from the source region 1012C and the drain region 1016C to a center region of the channel region 1014C. The descriptions of the source region 1012C, the channel region 1014C, and the drain region 1016C can be referred to with respect to the descriptions of the source region 112C, the channel region 114C, and the drain region 116C described above with reference to FIG. 3C.

Referring to FIG. 12D, in the semiconductor body 1010D of the semiconductor device 500D, a source region 1012D and a drain region 1016D are doped with P+type impurities having a high concentration. In the semiconductor body 1010D, a channel region 1014D that is between the source region 1012D and the drain region 1016D is doped with P-type impurities having a high concentration and includes a region having a lower impurity doping concentration than that in the source region 1012D and the drain region 1016D. The channel region 1014D has a doping concentration gradient in which an impurity concentration varies according to a position from the source region 1012D and the drain region 1016D to a center region of the channel region 1014D. The descriptions of the source region 1012D, the channel region 1014D, and the drain region 1016D can be referred to with respect to the description of the source region 112D, the channel region 114D, and the drain region 116D described above with reference to FIG. 3D.

The channel regions 1014C and 1014D of the semiconductor devices 500C and 500D shown in FIGS. 12C and 12D may have an impurity doping concentration gradient according to any one of FIGS. 4A and 4C.

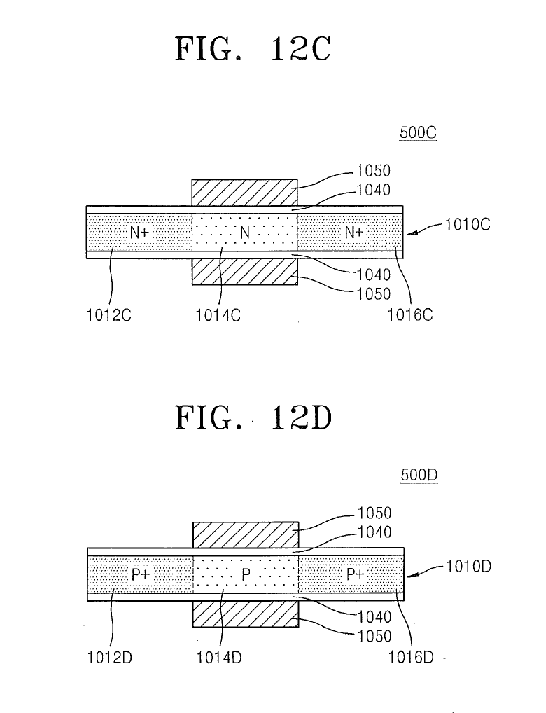

FIGS. 13A through 13C are perspective views showing sequential processes of a method of manufacturing a semiconductor device, according to an embodiment of the inventive concept.

Like reference numerals in FIGS. 10 through 12D and 13A through 13C denote like elements and a repeated description thereof is not provided.

Referring to FIG. 13A, a semiconductor pattern 1310 including a semiconductor region having a nanowire shape is formed on an insulating layer 104 that is formed on a substrate 102 via a general process.

The semiconductor pattern 1310 includes a first portion P1, a second portion P2, and a third portion P3 that extends in a nanowire shape between the first portion P1 and the second portion P2 and is spaced apart from the insulating layer 104.

Widths W1 and W2 of the first portion P1 and the second portion P2, which are measured in a Y-axis direction in FIG. 13A, are each greater than a width W3 of the third portion P3. In some embodiments, the width W3 of the third portion P3 is several tens of nm. For example, the width W3 of the third portion P3 may be about 20 to about 30 nm. A detailed shape of the semiconductor pattern 1310 is not limited to a shape shown in FIG. 13A and may be changed in various ways according to a design.

Referring of FIG. 13B, impurity ions 1320 of a single conductivity type are injected into the semiconductor pattern 1310 across an entire region. The resulting structure is then heat-treated to activate the impurity ions that are injected into the semiconductor pattern 1310 so as to form a semiconductor pattern 1310A doped with a high concentration of impurities by using a method described with reference to FIG. 5B.

The semiconductor pattern 1310A includes the first pad region 1006, the second pad region 1008, and the semiconductor body 1010 that extends between the first pad region 1006 and the second pad region 1008. The semiconductor body 1010 has a nanowire shape, as shown in FIGS. 10, 11A, and 11B. The semiconductor body 1010 includes the source region 1012, the channel region 1014, and the drain region 1016 that are sequentially formed in a longitudinal direction, as shown in FIG. 11 A.

In some embodiments, in order to form the semiconductor body 1010, N-type impurities may be injected into the semiconductor pattern 1310. In this case, the semiconductor body 1010 has a structure such as the semiconductor body 1010A including the source region 1012A, the channel region 1014A, and the drain region 1016A, which include N+ type doping regions, as shown in FIG. 12A. In other embodiments, in order to form the semiconductor body 1010, P-type impurity ions may be injected into the semiconductor pattern 1310. In this case, the semiconductor body 1010 has a structure such as the semiconductor body 1010B including the source region 1012B, the channel region 1014B, and the drain region 1016B, which include a P+ type doping region, as shown in FIG. 12B.

Referring to FIG. 13C, the gate dielectric layer 1040 is formed on an exposed surface of the semiconductor body 1010. In order to form the gate dielectric layer 1040, an ALD method or a metal organic ALD (MOALD) method may be used.

Then, a gate electrode material including metal is deposited on the gate dielectric layer 1040 only around the channel region 1014 of the semiconductor body 1010 to form the gate electrode 1050, as shown in FIG. 10. In order to deposit the gate electrode material on the gate dielectric layer 1040, an ALD method or an MOALD method may be used.

In order to form the semiconductor body 1010C having a doping concentration gradient in the channel region 1014C, as shown in FIG. 12C, or the semiconductor body 1010D having a doping concentration gradient in the channel region 1014D, as shown in FIG. 12D, an ion injection mask pattern for covering portions of the semiconductor pattern 1310, on which the channel region 1014C or 1014D is to be formed, may be formed before the impurity ions 1320 having a single conductivity type are injected, as shown in FIG. 13B. In addition, the impurity ions 1320 may be injected into portions of the semiconductor pattern 1310, which are covered by the ion injection mask pattern, to form the source region 1012C or 1012D and the drain region 1016C or 1016D. Then, as described with reference to FIG. 6D, the resulting structure including the source region 1012C or 1012D and the drain region 1016C or 1016D is heat-treated to diffuse dopants from the source region 1012C or 1012D and from the drain region 1016C or 1016D into the semiconductor pattern 1310 between the source region 1012C or 1012D and the drain region 1016C or 1016D so as to form the channel region 1014C or 1014D having a doping concentration gradient below an ion injection mask on the semiconductor pattern 1310.

Then, the ion injection mask pattern is removed such that the gate dielectric layer 1040 and the gate electrode 1050 may be formed on the semiconductor body 1010C or 1010D.

The semiconductor devices described with reference to FIGS. 1 through 13C include a semiconductor body including a source region, a channel region, and a drain region, which are sequentially formed in a longitudinal direction and are doped with the same conductivity type dopants, and a junction-less transistor that includes a metal gate electrode covering the channel region of the semiconductor body. Since metal is used as the gate electrode, thermal budget is reduced during formation of the gate electrode so as to reduce adverse effects to the doping profile in the semiconductor body and to reduce the likelihood that dopants are diffused into the semiconductor body during formation of the gate electrode in order to maintain the performance and electrical properties of the transistor compared with a case where a gate electrode is formed using doped polysilicon.

In addition, since the gate electrode is formed of metal having low reactivity with respect to a high dielectric layer, even if a high dielectric layer is used as a gate dielectric layer, an undesired reaction between the high dielectric layer and the gate electrode may be avoided so as to provide a transistor having improved performance and a low resistance. In addition, a semiconductor device according to an embodiment of the inventive concept includes a semiconductor body in which a center region of a transistor has a doping concentration that is substantially 0 or which has a doping concentration gradient in a channel region to have a lower concentration than that of a source region and a drain region so as to increase the on/off properties of the transistor.

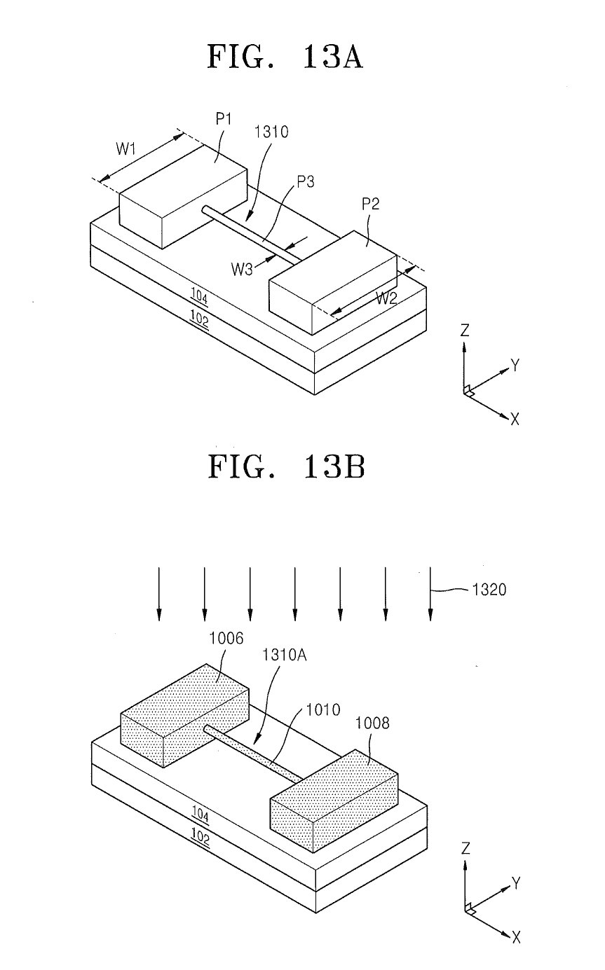

FIG. 14 is a plan view of a memory module 1500 according to an embodiment of the inventive concept.

The memory module 1500 includes a module substrate 1510 and a plurality of semiconductor chips 1520 attached to the module substrate 1510.

The semiconductor chip 1520 includes a semiconductor device according to an embodiment of the inventive concept. For example, the semiconductor chip 1520 may include one (or more) of the semiconductor devices shown in FIGS. 1 through 12D.

Connection portions 1530 inserted into a socket of a mother board are disposed on one side of the module substrate 1510. Ceramic decoupling capacitors 1540 are disposed on the module substrate 1510. The memory module 1500 is not limited to the structure shown in FIG. 14 and may be changed in various ways.

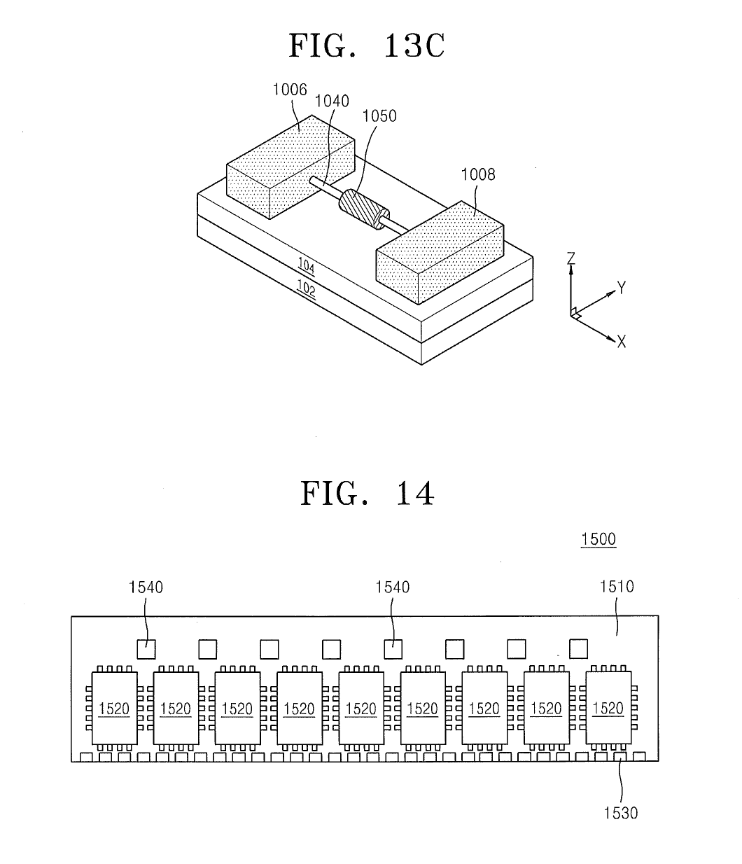

FIG. 15 is a block diagram of a system 1600 according to an embodiment of the inventive concept.

The system 1600 includes a controller 1610, an input/output device 1620, a memory device 1630, and an interface 1640. The system 1600 may be a mobile system or a system for transmitting or receiving information. In some embodiments, the mobile system may be a personal digital assistant (PDA), a portable computer, a web tablet, a wireless phone, a mobile phone, a digital music player, or a memory card. The controller 1610 controls an execution program of the system 1600 and may include a microprocessor, a digital signal processor, a microcontroller, or a similar device. The input/output device 1620 may be used to input or output data to or from the system 1600. The system 1600 may be connected to an external device, for example, a personal computer or a network via the input/output device 1620 and may exchange data with the external device. The input/output device 1620 may be, for example, a keypad, a keyboard, or a display.

The memory device 1630 may store a code and/or data for an operation of the controller 1610 or may store data processed in the controller 1610. The memory device 1630 includes a semiconductor device according to an embodiment of the inventive concept. For example, the memory device 1630 may include the semiconductor devices shown in FIGS. 1 through 12D.

The interface 1640 may be a data transmission path between the system 1600 and another external device. The controller 1610, the input/output device 1620, the memory device 1630, and the interface 1640 may communicate with each other via a bus 1650. The system 1600 may be used in a mobile phone, an MP3 player, a navigation device, a portable multimedia player (PMP), a solid state disk (SSD), or household appliances.

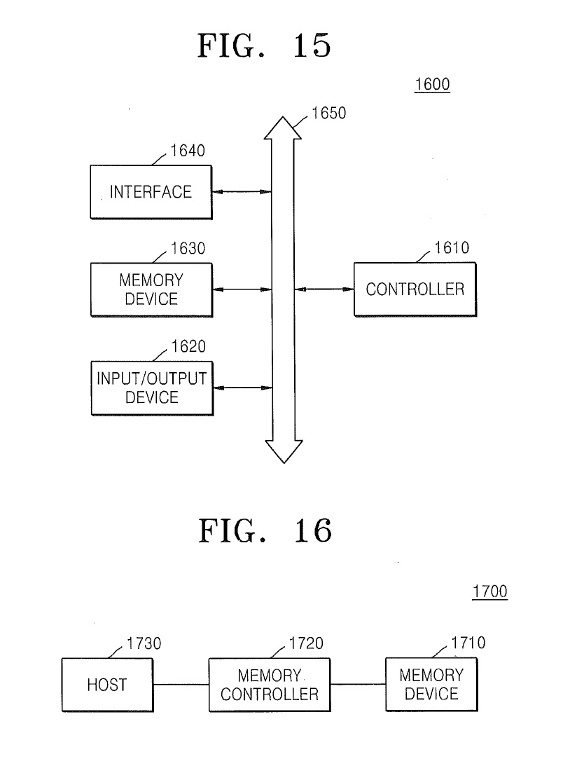

FIG. 16 is a block diagram of a memory card 1700 manufactured by using a method of manufacturing a magnetic device, according to an embodiment of the inventive concept.

The memory card 1700 includes a memory device 1710 and a memory controller 1720.

The memory device 1710 may store data. In some embodiments, the memory device 1710 has nonvolatile properties whereby stored data is retained when power is shut off. The memory device 1710 includes a semiconductor device according to an embodiment of the inventive concept. For example, the memory device 1710 may include the semiconductor devices shown in FIGS. 1 through 12D.

The memory controller 1720 may read data stored in the memory device 1710 or may store data of the memory device 1710 in response to a read/write request of a host 1730.

While the inventive concept has been particularly shown and described with reference to exemplary embodiments thereof, it will be understood that various changes in form and details may be made therein without departing from the spirit and scope of the following claims.

1. A semiconductor device comprising:
a semiconductor body comprising a source region, a channel region, and a drain region, which are sequentially arranged in a longitudinal direction and are doped with the same type of impurity;
a gate electrode formed on the channel region and comprising metal; and
a gate dielectric layer disposed between the semiconductor body and the gate electrode.

2. The semiconductor device of claim 1, wherein the channel region has a doping concentration gradient in which an impurity concentration varies according to a position from the source region and the drain region to a center region of the channel region.

3. The semiconductor device of claim 1, wherein the channel region has a doping concentration that increases toward the source region and the drain region and a lowest doping concentration in a center region of the channel region.

4. The semiconductor device of claim 1, wherein the channel region comprises a depletion region that is in a center region between the source region and the drain region and in which a carrier does not substantially exist.

5. The semiconductor device of claim 1, wherein the source region and the drain region have a doping concentration selected from a range of about 1×10²⁰ to about 1×10²³ atoms/cm³.

6. The semiconductor device of claim 1, wherein a PN junction is not formed in the semiconductor body.

7. The semiconductor device of claim 1, wherein the gate electrode comprises at least one material selected from metal, metal nitride, and metal carbide.

8. The semiconductor device of claim 1, wherein the gate dielectric layer comprises a high dielectric layer having a higher dielectric constant than that of a silicon oxide layer.

9. The semiconductor device of claim 1, wherein the semiconductor body comprises a fin-type structure having an upper surface and opposite lateral walls, and
wherein the gate dielectric layer and the gate electrode cover the upper surface and the opposite lateral walls of the semiconductor body on the channel region.

10. The semiconductor device of claim 1, wherein the semiconductor body has a nanowire shape, and
wherein the gate dielectric layer and the gate electrode surround the semiconductor body on the channel region.

11. A semiconductor device comprising:
a first MOS transistor comprising a first semiconductor body including a first source region, a first channel region, and a first drain region, which are sequentially arranged in a longitudinal direction of the first semiconductor body and are doped with a first conductivity type impurity; a first gate electrode formed on the first channel region and including a first metal; and a gate dielectric layer interposed between the first semiconductor body and the first gate electrode, and
a second MOS transistor comprising a second semiconductor body including a second source region, a second channel region, and a second drain region, which are sequentially arranged in a longitudinal direction of the second semiconductor body and are doped with a second conductivity type impurity that is opposite to the first conductivity type impurity; a second gate electrode formed on the second channel region and including a second metal that is different from the first metal; and a second gate dielectric layer interposed between the second semiconductor body and the second gate electrode.

12. The semiconductor device of claim 11, wherein the first channel region has a doping concentration gradient in which an impurity doping concentration varies in a longitudinal direction of the first channel region and/or the second channel region has a doping concentration gradient in which an impurity doping concentration varies in a longitudinal direction of the second channel region.

13. The semiconductor device of claim 11, wherein the first channel region has a lowest doping concentration in a center portion of the first channel region and has a doping concentration that increases away from the center portion in a longitudinal direction of the first channel region and/or the second channel region has a lowest doping concentration in a center portion of the second channel region and has a doping concentration that increases away from the center portion in a longitudinal direction of the second channel region.

14. The semiconductor device of claim 11, wherein at least one channel region of the first channel region and the second channel region comprises a depletion region in which a carrier does not substantially exist.

15. The semiconductor device of claim 11, wherein the first gate electrode comprises at least one first work function metal layer selected from metal, metal nitride, and metal carbide,
wherein the second gate electrode comprises at least one second work function metal layer selected from metal, metal nitride, and metal carbide, and
wherein the first work function metal layer and the second work function metal layer comprise different metals.

16-20. (canceled)
